(19) United States
(12) Patent Application Publication
(10) Pub. No.: US 2004/0214426 A1
(43) Pub. Date: Oct. 28, 2004

(54) Method of manufacturing electronic device and energy beam absorbing material

(75) Inventor: Junjirou Sakai, Tokyo (JP)

Correspondence Address: MCDERMOTT, WILL & EMERY, 60013th Street, N.W., WASHINGTON, DC, 20005-3096, US

(73) Assignee: RENESAS TECHNOLOGY CORP.

(21) Appl. No.: 10/832,405

(22) Filed: Apr. 27, 2004

(30) Foreign Application Priority Data
Apr. 28, 2003 (JP) JP2003-123720

(51) Int. Cl. H01L 29/04; H01L 31/036; H01L 31/0376; H01L 31/20; H01L 21/4763; H01L 21/302; H01L 21/461

(52) U.S. Cl. 438/636

(57) ABSTRACT

An EB curing process is performed on a photoresist (7), with an energy beam absorbing film (5) formed on a low dielectric constant interlayer insulator film (4). The energy beam absorbing film (5) contains a compound represented by the following general formula:

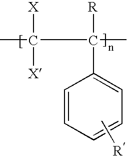

wherein at least one of X, X′, R and R′ is selected from the group consisting of bromine, iodine, an alkyl bromide and an alkyl iodide, and n is a positive integer. The compound represented by the general formula absorbs an electron beam well to make it difficult for the electron beam to reach the low dielectric constant interlayer insulator film (4) to be patterned.

### BACKGROUND OF THE INVENTION

1. Field of the Invention

The present invention relates to a method of manufacturing an electronic device including the step of patterning a low dielectric constant interlayer insulator film, and an energy beam absorbing material.

2. Description of the Background Art

With the performance enhancement of semiconductor devices, it has been a challenge to reduce the resistances of multi-level interconnect lines formed on a semiconductor substrate and capacitances between interconnect lines.

To reduce the interconnect resistances, a technique has been employed in which copper having a low resistance is used as an interconnect material in place of conventional materials such as aluminum and tungsten. To reduce the capacitances between interconnect lines, on the other hand, a technique has been employed in which, for example, an SiOF (fluorine doped silicon oxide) film is used as an interlayer insulator film in place of a conventionally used silicon oxide film by the introduction of fluorine.

The SiOF film has a low dielectric constant to contribute to the reduction in the capacitances between interconnect lines. Other films than the SiOF film having been used as a low dielectric constant interlayer insulator film include an SiOC (carbon doped silicon oxide) film in which a methyl group (—CH₃), a methoxy group (—OCH₃) or the like is bonded to silicon and in which carbon is contained.

In manufacturing semiconductor devices, it is necessary to form a fine pattern of photoresist by the use of a photolithography technique. However, the finer the pattern becomes, the greater the aspect ratio thereof is, and the more likely a so-called pattern collapse to occur. Further, an ArF or F₂ light source is being used in place of a conventional KrF light source as a light source for exposure of the photoresist. However, a photoresist for the ArF or F₂ light source generally has a high etch rate, and therefore must be formed to have an increased thickness.

These problems result from the insufficient resistance of the photoresist to etching. To solve the problems, a technique has been developed in which an energy beam including an electron beam (EB), deep ultra-violet (DUV) light, vacuum ultra-violet (VUV) light, and the like is directed onto a photoresist to alter the quality of a photoresist component, thereby improving the resistance to etching. Such a quality altering technique is generally referred to as a curing process. The use of a photoresist pattern subjected to the curing process suppresses film thickness reduction and deformations during etching to provide a satisfactorily patterned configuration.

Information on prior art documents relevant to the present invention includes: U.S. Pat. Nos. 6,495,305; 6,503,840; 6,465,361; and 6,319,655.

When a low dielectric constant interlayer insulator film is to be patterned, it has been impossible to perform the curing process on the photoresist. This is because the low dielectric constant interlayer insulator film is altered in quality by the energy beam passing through the photoresist to have an increased dielectric constant.

### SUMMARY OF THE INVENTION

It is an object of the present invention to provide a method of manufacturing an electronic device and an energy beam absorbing material which enable a curing process to be performed on a photoresist even when a low dielectric constant interlayer insulator film is to be patterned.

According to a first aspect of the present invention, a method of manufacturing an electronic device includes the following steps (a) to (d). The step (a) is to form a to-be-patterned film on a substrate. The step (b) is to form an energy beam absorbing film on the to-be-patterned film. The step (c) is to form a photoresist pattern on the energy beam absorbing film. The step (d) is to etch the to-be-patterned film by using the photoresist pattern as a mask. The energy beam absorbing film contains a compound represented by any one of General Formulas (I) to (III).

According to a second aspect of the present invention, an energy beam absorbing material is for forming a film between a to-be-patterned film and a photoresist for absorbing an energy beam directed onto the photoresist to prevent the energy beam from reaching the to-be-patterned film during photolithography. The energy beam absorbing material contains a compound represented by any one of General Formulas (I) to (III).

General Formula (I) is:

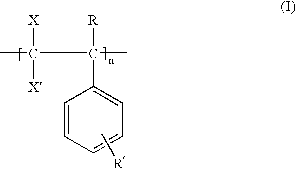

wherein at least one of X, X′, R and R′ is selected from the group consisting of bromine, iodine, an alkyl bromide and an alkyl iodide, and n is a positive integer.

General Formula (II) is:

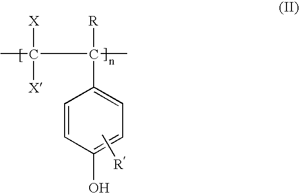

wherein at least one of X, X′, R and R′ is selected from the group consisting of bromine, iodine, an alkyl bromide and an alkyl iodide, and n is a positive integer.

General Formula (III) is:

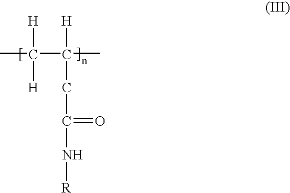

wherein R is an aromatic compound, and n is a positive integer.

When the energy beam is an electron beam, the compound represented by General Formula (I) or (II) absorbs the energy beam well to make it difficult for the energy beam to reach the to-be-patterned film. This enables a curing process to be performed on the photoresist if a low dielectric constant interlayer insulator film is used as the to-be-patterned film.

When the energy beam is DUV light or VUV light, the compound represented by General Formula (III) absorbs the energy beam well to make it difficult for the energy beam to reach the to-be-patterned film. This enables a curing process to be performed on the photoresist if a low dielectric constant interlayer insulator film is used as the to-be-patterned film.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 through 11 are views showing respective process steps in a method of manufacturing an electronic device according to first and second preferred embodiments of the present invention; and

FIG. 12 shows changes in the dielectric constant of a low dielectric constant interlayer insulator film depending on whether an energy beam absorbing film is present or absent according to the first and second preferred embodiments.

### DESCRIPTION OF THE PREFERRED EMBODIMENTS

<First Preferred Embodiment>

A first preferred embodiment of the present invention provides a method of manufacturing an electronic device which uses a film containing a material selected from the group consisting of bromine, iodine, an alkyl bromide and an alkyl iodide as an energy beam absorbing film during a curing process.

FIGS. 1 through 11 are views showing respective process steps in the method of manufacturing an electronic device according to the first preferred embodiment.

First, as shown in FIG. 1-, a first low dielectric constant interlayer insulator film 1 of SiOC, SiOF or the like is formed on a semiconductor substrate 0 such as a silicon substrate. Then, a contact hole is formed in the first low dielectric constant interlayer insulator film 1. Copper or the like fills the contact hole by a plating process or the like and is subjected to a CMP (chemical mechanical polishing) process to form a contact plug 2.

Next, an etch stopper film 3 of silicon nitride or the like, and a second low dielectric constant interlayer insulator film 4 of SiOC, SiOF or the like are formed in the order named on the surfaces of the first low dielectric constant interlayer insulator film 1 and the contact plug 2. In this preferred embodiment, the second low dielectric constant interlayer insulator film 4 is a film to be patterned.

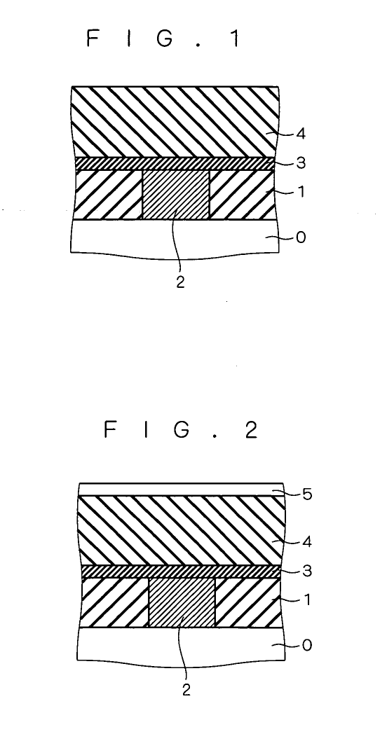

Next, an energy beam absorbing film 5 is formed on the second low dielectric constant interlayer insulator film 4, as shown in FIG. 2. The energy beam absorbing film 5 contains a compound represented by the following formula:

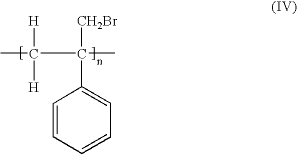

wherein n is a positive integer.

The energy beam absorbing film 5 is formed in a manner to be described below. A thinner in which the compound of Formula (IV) is dissolved is spin-coated onto the second low dielectric constant interlayer insulator film 4. Then, the application of heat evaporates the thinner component to solidify a film containing the compound of Formula (IV) as a principal component on the second low dielectric constant interlayer insulator film 4.

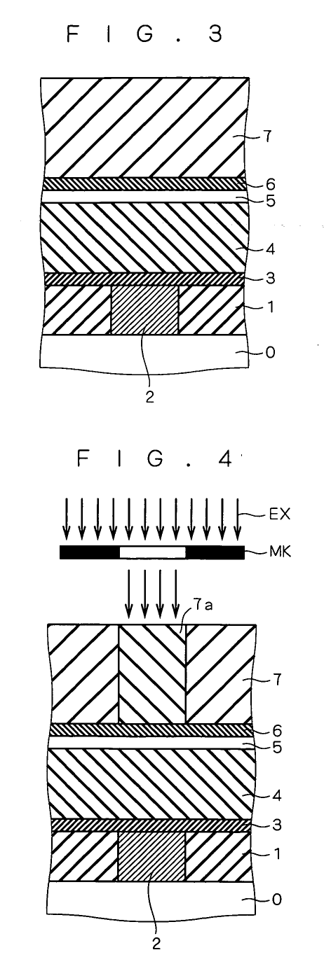

Next, as shown in FIG. 3, an anti-reflection film 6 containing an organic compound as a principal component on the energy beam absorbing film 5. Then, a photoresist 7 is formed on the anti-reflection film 6.

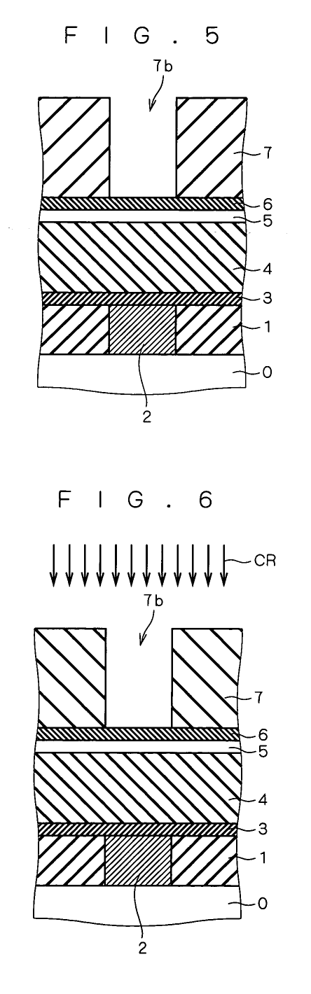

Next, as shown in FIG. 4, the photoresist 7 is exposed to light EX through a photomask MK having an exposure pattern, whereby an exposed portion 7a is formed. Then, a development process using an alkaline developer is performed to form a pattern 7b in the photoresist 7, as shown in FIG. 5.

Next, as shown in FIG. 6, an EB curing apparatus is used to direct an electron beam CR having, for example, an acceleration voltage of 25 keV and a charge density of 500 μC/cm² onto the photoresist 7. This curing process modifies the photoresist 7.

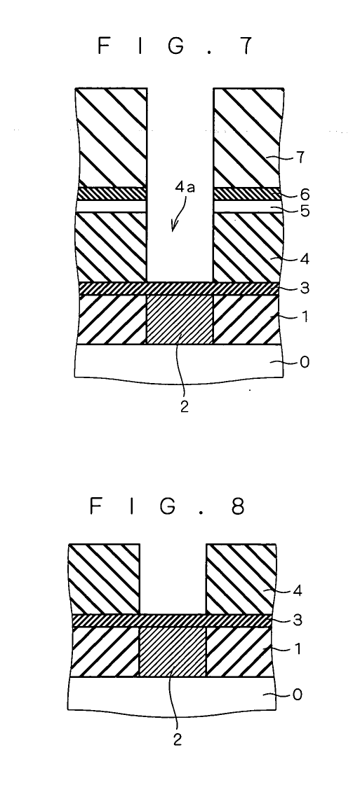

Next, as shown in FIG. 7, etching is performed on the anti-reflection film 6, the energy beam absorbing film 5 and the second low dielectric constant interlayer insulator film 4, using the photoresist 7 as an etch mask. This provides a trench pattern 4a formed in the second low dielectric constant interlayer insulator film 4. The presence of the etch stopper film 3 prevents the trench pattern 4a from being formed in the first low dielectric constant interlayer insulator film 1.

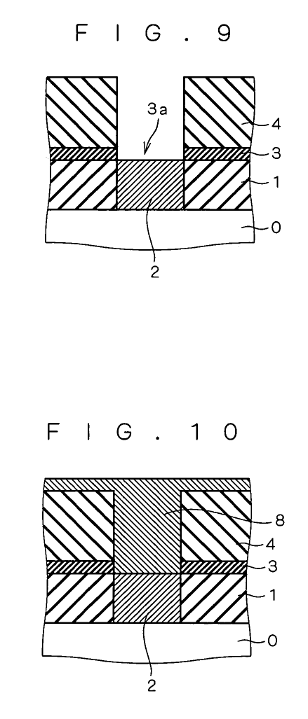

Next, as shown in FIG. 8, a plasma ashing process is performed to remove the photoresist 7, the anti-reflection film 6 and the energy beam absorbing film 5. Then, as shown in FIG. 9, etching is also performed on the etch stopper film 3 to provide an opening 3a, thereby exposing the underlying contact plug 2.

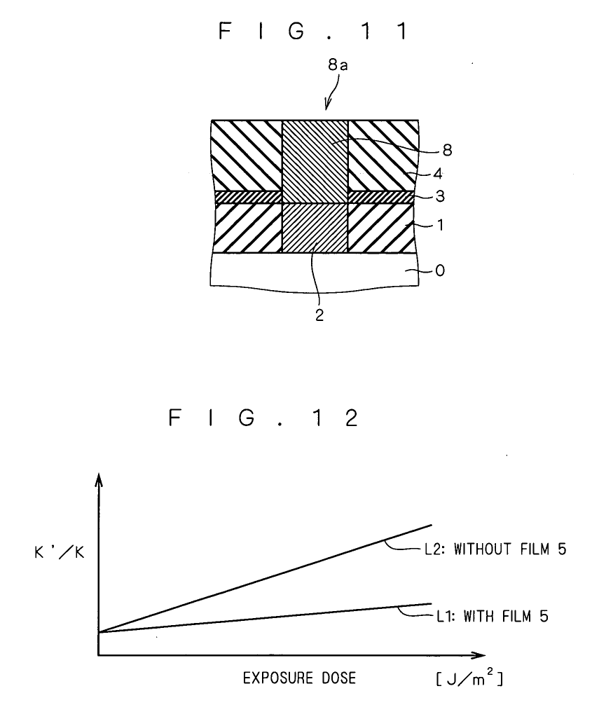

Next, as shown in FIG. 10, an interconnect material 8 such as a copper fills the trench patterns 3a and 4a by a plating process or the like. Then, as shown in FIG. 11, a CMP process is performed on the interconnect material 8 to planarize a surface 8a thereof.

The energy beam absorbing film 5 containing the compound of Formula (IV) as a principal component is formed in the first preferred embodiment. The presence of the energy beam absorbing film 5 made it difficult for the electron beam CR during the curing process to reach the second low dielectric constant interlayer insulator film 4.

FIG. 12 shows changes in the dielectric constant of the second low dielectric constant interlayer insulator film 4 with and without the energy beam absorbing film 5. Specifically, the vertical axis of FIG. 12 indicates a K′/K ratio between the dielectric constant K′ of the second low dielectric constant interlayer insulator film 4 after the curing process and the dielectric constant K thereof before the curing process, and the horizontal axis indicates the exposure dose of the electron beam CR.

In FIG. 12, the line L1 plotted in the case where the energy beam absorbing film 5 is present shows that the K′/K ratio between the dielectric constants before and after the curing process is less prone to be changed by the increase in the exposure dose of the electron beam CR than the line L2 plotted in the case where the energy beam absorbing film 5 is absent. This means that the dielectric constant of the second low dielectric constant interlayer insulator film 4 increases very little if the curing process is performed in the presence of the energy beam absorbing film 5.

The compound of Formula (IV) contains bromine, which is a halogen, in the form of an alkyl bromide, CH₂Br, and bromine particularly absorbs the electron beam CR well. For this reason, it is considered difficult for the electron beam CR to reach the second low dielectric constant interlayer insulator film 4.

Similar process steps and measurements performed on other materials than the compound of Formula (IV) have revealed that the compound of Formula (IV) may contain another alkyl bromide such as CHBr₂ or CBr₃ or a bromine atom itself in place of CH₂Br or may otherwise contain iodine, which is another halogen, or an alkyl iodide such as CH₂I, CH₁₂, or CI₃.

It has also been found that bromine, iodine, an alkyl bromide or an alkyl iodide may be located in the position of a hydrogen atom in addition to the position of CH₂Br in Formula (IV), and that bromine, iodine, an alkyl bromide or an alkyl iodide may be substituted for a hydrogen atom in the benzene ring.

In summary, the energy beam absorbing film 5 is required only to contain a compound including the compound of Formula (IV) and represented by the following general formula:

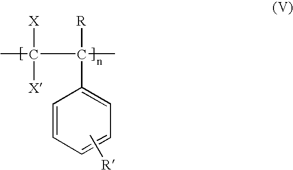

wherein at least one of X, X′, R and R′ is selected from the group consisting of bromine, iodine, an alkyl bromide and an alkyl iodide, and n is a positive integer.

Although General Formula (V) represents a styrene-like compound in which a benzene ring is bonded to a carbon atom, the energy beam absorbing film 5 may contain a phenol-like compound represented by the following general formula:

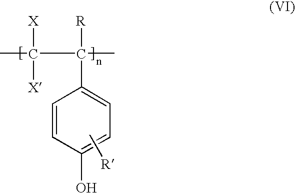

wherein at least one of X, X′, R and R′ is selected from the group consisting of bromine, iodine, an alkyl bromide and an alkyl iodide, and n is a positive integer.

Styrene resin, phenolic resin or novolac resin which is a typical material constituting the anti-reflection film may also be used as a material containing the compounds of General Formulas (V) and (VI).

The method of manufacturing an electronic device and the energy beam absorbing material according to the first preferred embodiment have an advantage that when the energy beam is the electron beam, the compound represented by General Formula (V) or (VI) absorbs the energy beam well to make it difficult for the electron beam to reach the second low dielectric constant interlayer insulator film 4 to be patterned. Therefore, the first preferred embodiment enables the curing process to be performed on the photoresist if a low dielectric constant interlayer insulator film is adopted as a film to be patterned.

<Second Preferred Embodiment>

A second preferred embodiment of the present invention provides a modification of the method of manufacturing an electronic device and the energy beam absorbing material according to the first preferred embodiment. The second preferred embodiment is such that the material of the energy beam absorbing film 5 of the first preferred embodiment is changed to a material to be described below, and the energy beam is changed to DUV light or VUV light.

The process steps shown in FIGS. 1 through 11 are also performed in the second preferred embodiment. The energy beam absorbing film 5 shown in FIG. 2 contains a compound represented below by Formula (VII) in place of the compound represented by Formula (IV).

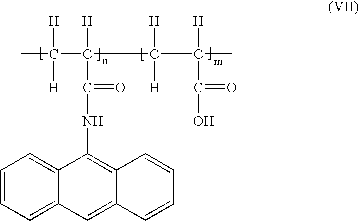

wherein m and n are positive integers.

The energy beam absorbing film 5 is formed by spin-coating a thinner in which the compound of Formula (VII) is dissolved onto the second low dielectric constant interlayer insulator film 4, and then applying heat, as in the first preferred embodiment.

Thereafter, the process step of FIG. 3 and its subsequent process steps are performed as in the first preferred embodiment, but the curing process shown in FIG. 6 is a DUV curing process or a VUV curing process according to the second preferred embodiment. For the DUV curing process, a DUV curing apparatus may be used to direct DUV light having, for example, a wavelength of 190 to 350 nm as the energy beam onto the photoresist 7. For the VUV curing process, a VUV curing apparatus may be used to direct VUV light having, for example, a wavelength of 172 nm as the energy beam onto the photoresist 7.

The second preferred embodiment is otherwise similar to the method of manufacturing an electronic device and the energy beam absorbing material of the first preferred embodiment, and will not be described.

The energy beam absorbing film 5 containing the compound of Formula (VII) as a principal component is formed in the second preferred embodiment. The measurement results in this case were similar to those shown in FIG. 12. The presence of the energy beam absorbing film 5 made it difficult for the DUV light and the VUV light during the curing process to reach the second low dielectric constant interlayer insulator film 4.

The compound of Formula (VII) contains anthracene, which is an aromatic compound, in the form of an aromatic-substituted alkylamine, and anthracene particularly absorbs the DUV light and the VUV light well. For this reason, it is considered difficult for the DUV light and the VUV light to reach the second low dielectric constant interlayer insulator film 4.

Similar process steps and measurements performed on other materials than the compound of Formula (VII) have revealed that the compound of Formula (VII) may contain another aromatic compound such as benzene, naphthalene or pyridine in place of anthracene. It has also been found that the use of benzene and anthracene is suitable for the DUV curing process, and the use of naphthalene and pyridine is suitable for the VUV curing process.

Therefore, the energy beam absorbing film 5 is required only to contain a compound including the compound of Formula (VII) and represented by the following general formula:

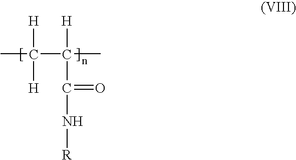

wherein R is an aromatic compound, and n is a positive integer.

Acrylamide resin which is a typical material constituting the anti-reflection film may also be used as a material containing the compound of General Formula (VIII).

The method of manufacturing an electronic device and the energy beam absorbing material according to the second preferred embodiment have an advantage that when the energy beam is the DUV light or the VUV light, the compound represented by General Formula (VIII) absorbs the energy beam well to make it difficult for the DUV light or the VUV light to reach the second low dielectric constant interlayer insulator film 4 to be patterned. Therefore, the second preferred embodiment enables the curing process to be performed on the photoresist if a low dielectric constant interlayer insulator film is adopted as a film to be patterned.

<Modifications>

The present invention has been described in the above-mentioned first and second preferred embodiments by taking as an example the method of manufacturing a semiconductor device in which a low dielectric constant interlayer insulator film is formed over the semiconductor substrate 0.

The present invention, however, is not limited to the method of manufacturing a semiconductor device, but is also applicable to a method of manufacturing a variety of electronic devices such as a liquid crystal display device and a magnetic head.

While the invention has been described in detail, the foregoing description is in all aspects illustrative and not restrictive. It is understood that numerous other modifications and variations can be devised without departing from the scope of the invention.

What is claimed is:

1. A method of manufacturing an electronic device, comprising the steps of:
(a) forming a to-be-patterned film on a substrate;
(b) forming an energy beam absorbing film on said to-be-patterned film;
(c) forming a photoresist pattern on said energy beam absorbing film; and
(d) etching said to-be-patterned film by using said photoresist pattern as a mask,
wherein said energy beam absorbing film contains a compound represented by a general formula: 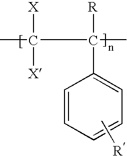
wherein at least one of X, X′, R and R′ is selected from the group consisting of bromine, iodine, an alkyl bromide and an alkyl iodide, and n is a positive integer.

2. A method of manufacturing an electronic device, comprising the steps of:
(a) forming a to-be-patterned film on a substrate;
(b) forming an energy beam absorbing film on said to-be-patterned film;
(c) forming a photoresist pattern on said energy beam absorbing film; and
(d) etching said to-be-patterned film by using said photoresist pattern as a mask,
wherein said energy beam absorbing film contains a compound represented by a general formula: 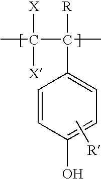
wherein at least one of X, X′, R and R′ is selected from the group consisting of bromine, iodine, an alkyl bromide and an alkyl iodide, and n is a positive integer.

3. A method of manufacturing an electronic device, comprising the steps of:
(a) forming a to-be-patterned film on a substrate;
(b) forming an energy beam absorbing film on said to-be-patterned film;
(c) forming a photoresist pattern on said energy beam absorbing film; and
(d) etching said to-be-patterned film by using said photoresist pattern as a mask,
wherein said energy beam absorbing film contains a compound represented by a general formula: 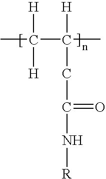
wherein R is an aromatic compound, and n is a positive integer.

4. An energy beam absorbing material for forming a film between a to-be-patterned film and a photoresist for absorbing an energy beam directed onto said photoresist to prevent said energy beam from reaching said to-be-patterned film during photolithography, said energy beam absorbing material comprising a compound represented by a general formula: 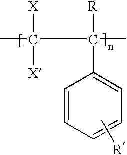
wherein at least one of X, X′, R and R′ is selected from the group consisting of bromine, iodine, an alkyl bromide and an alkyl iodide, and n is a positive integer.

5. An energy beam absorbing material for forming a film between a to-be-patterned film and a photoresist for absorbing an energy beam directed onto said photoresist to prevent said energy beam from reaching said to-be-patterned film during photolithography, said energy beam absorbing material comprising a compound represented by a general formula: 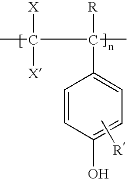
wherein at least one of X, X′, R and R′ is selected from the group consisting of bromine, iodine, an alkyl bromide and an alkyl iodide, and n is a positive integer.

6. An energy beam absorbing material for forming a film between a to-be-patterned film and a photoresist for absorbing an energy beam directed onto said photoresist to prevent said energy beam from reaching said to-be-patterned film during photolithography, said energy beam absorbing material comprising a compound represented by a general formula: 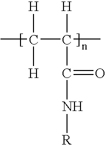
wherein R is an aromatic compound, and n is a positive integer.
